(19) United States
(12) Patent Application Publication
(10) Pub. No.: US 2008/0037202 A1
(43) Pub. Date: Feb. 14, 2008

(54) ELECTRONIC EQUIPMENT

(76) Inventors: Hidenori Shinohara, Yokohama (JP); Masami Takada, Fujisawa (JP); Hiroshi Hoshi, Yokohama (JP); Toshiyuki Moriya, Tokorozawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/675,706

(22) Filed: Feb. 16, 2007

(30) Foreign Application Priority Data
Aug. 10, 2006 (JP) 2006-217719

(51) Int. Cl. H05K 5/02

(52) U.S. Cl. 361/679

(57) ABSTRACT

It is an object of the present invention to provide an electronic equipment of a high design property having an optical disc drive mounted thereon and an inexpensive and high-quality opening and closing mechanism for a tray door. The electronic equipment includes a front panel on a front surface of the equipment, and a link 25 rotatably engaged with a tray door 22. The tray door is provided with cams 22b engaged with cam pins 20b provided on the front panel to control the locus of the movement of the tray door. The discharging movement of the tray causes the link to be pushed and rotated by the tray, whereby the tray door is slid to below the tray with its upper design surface left turned upwards in the form of the movement controlled by the rotation of the link and the locus of the cams, and in this manner, the tray door is opened. The link is pressurized by a torsion spring in a rotational direction to push a tray for an optical disc, and when the tray is retracted, the tray door is closed by the pressurization applied to the link by the torsion spring.

### INCORPORATION BY REFERENCE

The present application claims priority from Japanese application JP2006-217719 filed on Aug. 10, 2006, the content of which is hereby incorporated by reference into this application.

### BACKGROUND OF THE INVENTION

1. Field of the Invention

The present invention relates an electronic equipment having an optical disc drive mounted thereon, and particularly, to a tray door on a front surface of the optical disc drive.

2. Description of the Related Art

In recent years, an electronic equipment such as a of a DVD recorder for recording and regenerating an image and a voice in a combination of a DVD (Digital Versatile Disc) and a hard disc has been introduced, and the market thereof is increasing because of the less deterioration of the recorded image and voice and a good convenience. In recent years, on the other hand, in a flat television set employing a thin panel such as a liquid crystal panel and a plasma panel, the sales of which has increased, the utilization of an open television rack employing a shelf plate of glass is being increased. For this reason, the electronic equipment such as the DVD recorder is placed on the television rack in increased cases, and a high-quality design taking account of a visibility from the above and side is desired.

FIG. 11 is a side view of an equipment, showing a field of view of one display tube in the prior art. A front panel 50 is attached to an equipment body 51. Reference character 52 designates a viewing position of the display tube contained in a front panel. In the prior art, the display tube is mounted substantially vertically, but a range of view field (a field of display view) enabling the recognition of the displaying provided by the display tube is only ensured in a range of about 30° substantially from a level line. For this reason, when the equipment is placed at a location lower in level, a person cannot recognize the contents of display, unless he lowers a point of view, when he is closer to the equipment.

Documents relating to the above-described electronic equipment include JP-A-2003-168875 and JP-A-2005-327354.

### BRIEF SUMMARY OF THE INVENTION

In the above-described prior art, there has been provided a front panel of a shape such that the front surface of the equipment is vertically narrowed down in order to bring the equipment body being small-sized into view. In many cases, a door having a design property is mounted on a front surface of a DVD drive, and an opening and closing mechanism for the door includes a mechanism of a type which allows the opening and closing movements of the tray door by the forward and backward movements of a tray of an optical disc equipment contained in the DVD drive. The mechanism has an enhanced decency in respect of its movement.

In the prior art, the tray door is pushed by the opening or closing movement of the tray of the DVD drive and rotated about a hinge portion as a point of supporting.

In the prior art using the front panel of the shape such that the front surface of the equipment is vertically narrowed down, an opening is provided in a front surface of the front panel to provide a mechanism in which the disc is ejected or retracted directly by an optical disc drive, but the prior art does not provide a door or cover of a design property for completely covering the front surface of the optical disc drive.

The problem of the present invention is to realize and provide an electronic equipment of a high-design property including an inexpensive and high-quality tray door-opening/closing mechanism.

To solve the above problem, a design for a DVD recorder has been made which is an electronic equipment taking account of a visibility from the above and side in addition to the front of the equipment, as shown in FIG. 7. In the design of the electronic equipment shown in FIG. 7, an upper surface of a front panel is formed by a curved surface continuous from a front end to a top cover 1, and a large tray door is formed in a large size having an inclined surface such that its front end is tapered vertically to bring extremely thin vertically into view. It is an object of the present invention to realize a tray door-opening/closing mechanism for opening or closing the tray door having this inclined surface formed thereon to open or close the tray, thereby enabling the ejection or retraction of the disc.

The above object is achieved by the invention defined in claims.

The present invention provides an electronic equipment including a tray door-opening/closing mechanism having a good usability for a user.

Other objects, features and advantages of the invention will become apparent from the following description of the embodiments of the invention taken in conjunction with the accompanying drawings.

### BRIEF DESCRIPTION OF THE SEVERAL VIEW OF THE DRAWING

FIG. 1 is an exploded perspective view of an entire equipment according to an embodiment of the present invention;

FIG. 2 is an exploded perspective view of a front panel portion of the present invention;

FIG. 3 is a sectional view of a front portion, showing a state of a link when a tray door of the present invention has been closed;

FIG. 4 is a sectional view of the front portion, showing a state of the link when the tray door of the present invention has been opened;

FIG. 5 is a sectional view of the front portion, showing a state of cams of the tray door of the present invention when the tray door has been closed;

FIG. 6 is a sectional view of the front portion, showing a state of the cams of the tray door of the present invention when the tray door has been opened;

FIG. 7 is a perspective view showing a shape of the entire equipment of the present invention;

FIG. 8 is a perspective view showing a shape of the entire equipment of the present invention when the tray door has been opened;

FIG. 9 is a perspective view showing a shape of the entire equipment when a door at a front jack connection portion of the present invention has been opened;

FIG. 10 is a perspective view showing a shape of the entire equipment when a door at an IC card insertion portion of the present invention has been opened;

FIG. 11 is a side elevational view showing a field of view for a display tube in the prior art; and

FIG. 12 is a side elevational view showing a field of view for a display tube of the present invention.

### DETAILED DESCRIPTION OF THE INVENTION

A DVD recorder which is an electronic equipment according to the present invention will now be described with reference to the drawings.

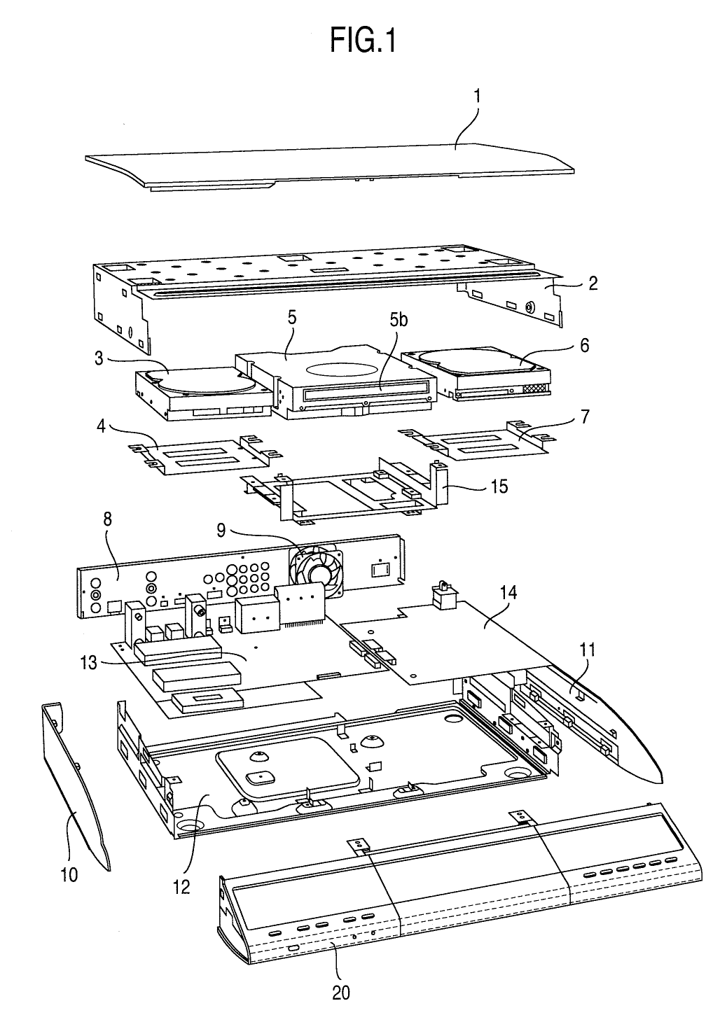

FIG. 1 is an exploded perspective view of the entire DVD recorder according to en embodiment of the present invention. The DVD recorder has a bottom case 12, to which the following components are fixed: a main board 13 on which a tuner, a record control circuit and the like are mounted, a power source board 14, a DVD holder 15, a rear panel 8 and a front panel 20. A fan 9 for removing an internal heat is fixed to the rear panel. A DVD drive 5 for recording an image is fixed to the DVD holder 15, and hard discs 3 and 6 are fixed to the bottom case through hard disc holders 4 and 7, respectively. The DVD drive is designed so that a tray portion 5b can be slid forwards and backwards by a power from a motor contained in the DVD drive through a control of interface with the main board, thereby permitting the ejection and retraction of a disc.

A top case 2 is fixed to the bottom case, and a top cover 1 and side covers 10 and 11 are attached in a sliding manner to the top case by a hook and fixed by a screw. The DVD drive is located at the center in a horizontal direction as viewed from the front, and a tray door 22 is located on a front surface of the DVD drive.

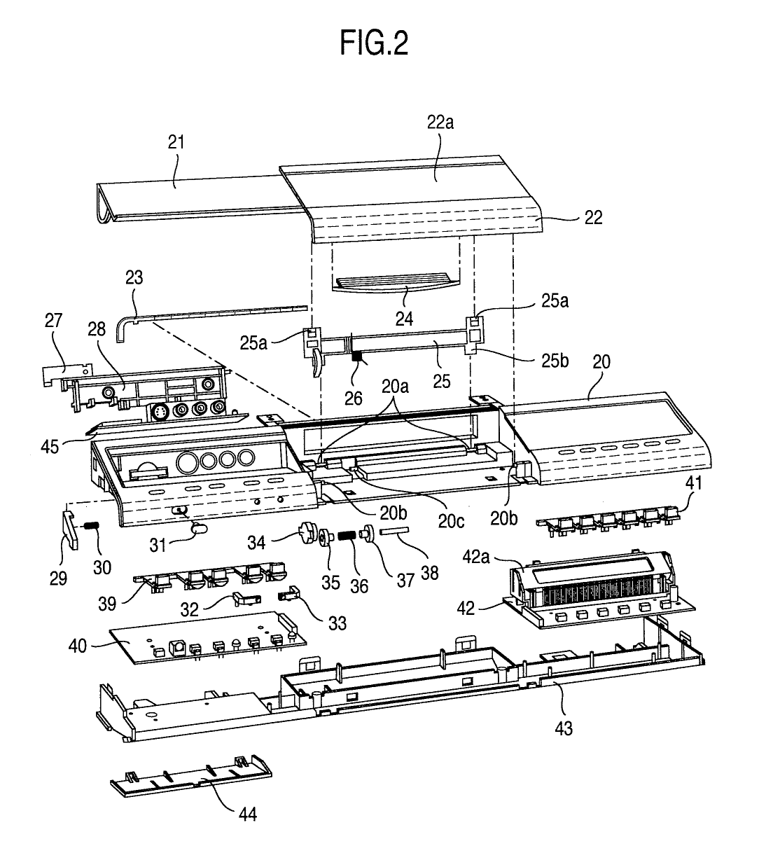

FIG. 2 shows an exploded perspective view of the front panel section. Mounted on the front panel 20 are a light sensor for an infrared remote control, an operating switch, a left front board 40 having an LED mounted thereon for indicating a recorded state, a sensor window 31 for guiding light of the infrared remote control to the light sensor, and recording indicators 32 and 33 for indicating the recording by the guiding of light of the LED. Also fixed to the front panel 20 by screws are a left button 39 adapted to be operated by a user to operate a switch on the left front board 40, a right front board 42 on which an indicator tube 42a for indicating a motional state of the equipment and an operating switch are mounted, a right button 41 operated by the user to operate the switch on the right front board 42, a jack board 28 on which a front jack and a memory card slot are mounted, and a leaf spring 27. A link 25 has a hinge portion 25b rotatably engaged with a shaft portion 20a of the front panel, and a torsion spring 26 for biasing and pressurize the link 25 to push it backwards is fixed to a pin portion 20c of the front panel. Although being not shown in FIG. 2, the tray door 22 has a hinge portion engaged with the pin portion 25a of the link 25, and although being not shown in FIG. 2, cams provided on the left and right sides of the tray door are engaged with cam pins 20b on the front panel. Also attached to the front panel are a gear A37 engaged with a gear of the link, a shaft 38 engaged with the center of the gear, a gear B35 engaged with the shaft, an oil damper 34 engaged with the gear B, and a coil spring 36 engaged with the gear A and a cylindrical portion of the gear B.

When the link 25 is rotated in a proximal direction, the tray door 22 is pushed forwards by the pin portion 25a and moved downwards while being slid downwards in the proximal direction by virtue of the engagement of the cam pins and the cams. When the link is rotated, the gear A is rotated following the link. When the tray door is rotated in an opening direction, the coil spring is loosened to permit the slipping of the gear B, so that no loading is applied to the movement of the tray door. On the other hand, when the tray door is rotated in a closing direction, the coil spring is tightened to allow the gear B to be rotated, and the rotation is transmitted to the oil damper with which the gear B is engaged. In this way, a viscous loading is applied to the rotation of the tray door when being closed, so that the tray door is closed quietly.

A jack door 21 is a door on the front surface of a jack portion capable of being connected to any of various external equipments by a cable. The jack door 21 is engaged with the pin portion of the jack board holder 28 attached to the jack board 45, and a door-locking button 29 is rotatably engaged with the shaft formed on the front panel 20, although being not shown in FIG. 2. A door-locking spring 30 is mounted between the door-locking button and the front panel. The jack door is of a structure in which the jack door is biased and pressurized so as to be pushed from the back by the leaf spring 27, and is retained by the engagement of a claw of the door-locking button with a claw of the jack door and opened by the disengagement of the claw upon depression of the door-locking button. A front bottom case 43 is attached and fixed to the front panel by a screw, and a card door 44 is mounted in rotatable engagement to a hinge portion of a front bottom case.

A light guide tube 23 is attached to the front panel and adapted to receive the light from the LED mounted on the jack board 28 to deflect the light forwards, and an illumination guide 24 is attached to the tray door for guiding the light deflected forwards to a clear window 22a in the dray door 22. In a state in which the tray door has been closed, the light guided from the illumination guide can be viewed through the clear window, and in a state in which the tray door has been opened, the light deflected by the light guide tube substitutes the illumination in the ejection and retraction of the disk on the tray when the inside of a room is dark.

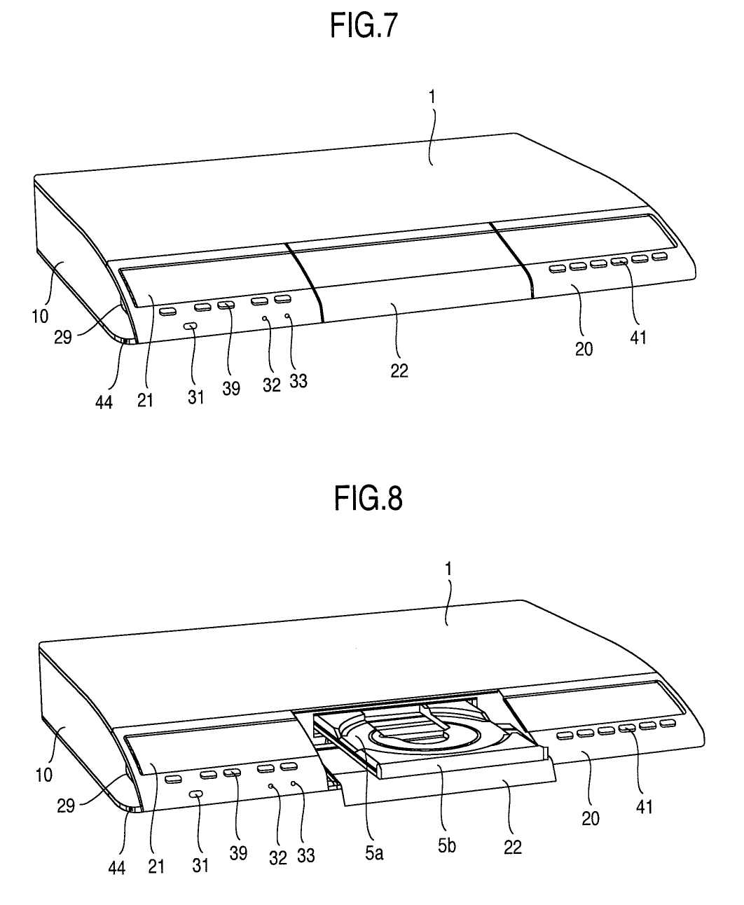

As shown in FIG. 7, a design of the DVD recorder which is the electronic element is made taking account of the visibility from the above and side in addition to the front of the equipment. In the design of the electronic equipment shown in FIG. 7, the upper surface of the front panel is formed by a curved surface continuous from the front end to the top cover 1, and the tray door is formed in a large size having an inclined surface such that its front end is tapered vertically to bring extremely thin vertically into view. The tray door 22 and the front panel 20 are formed laterally continuously with each other and connected to each other by curved lines forming vertically inclined surfaces, thereby forming a vertically curved surface, leading to the excellent design.

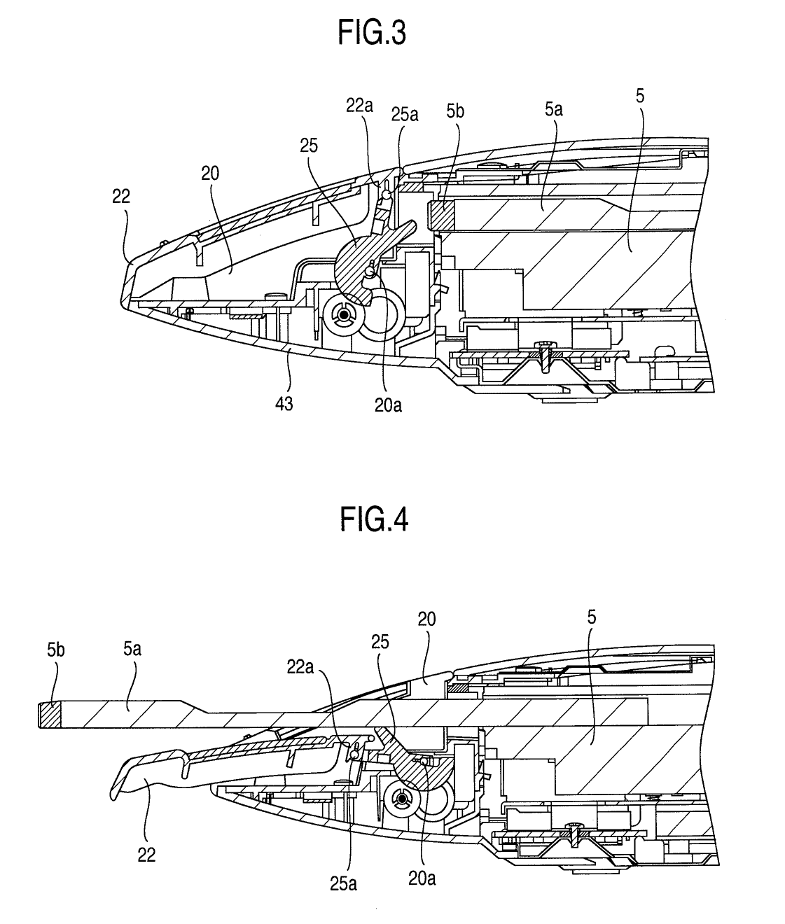

FIG. 3 is a sectional view of the front region showing a state of the link when the tray door has been closed. The link 25 has been engaged by the pin portion 20a of the front panel, and the tray door 22 has been engaged at its hinge portion 22a with the link 25. Although being not shown, the link 25 is biased and pressurized in a rightward rotational direction as viewed in FIG. 3 by the torsion spring. A tray 5a and a tray brand plate 5b as a design part on the front surface of the tray are contained in the DVD drive 5, so that the tray is opened and closed in a lateral direction as viewed in FIG. 3 by the driving of a motor which is not shown in FIG. 3. When the tray of the DVD drive is opened leftwards, the tray brand plate pushes the link, whereby the link is rotated in a counterclockwise direction about the hinge portion 20a to push the hinge portion 22a of the tray door in a leftward direction. In a state in which the tray door has been closed, the link is inclined slightly rightwards from the vertical, and when the tray door is pushed downwards from the above, the link is rotated in a clockwise direction and hence, the tray door is pushed in a closing direction, so that it cannot be opened inadvertently.

FIG. 4 is a sectional view of the front portion showing a state of the link when the tray door has been opened. The link 25 pushed by the tray brand plate 5b as a result of leftward opening of the tray 5a of the DVD drive 5 is rotated in a counterclockwise direction about the pin portion 20a of the front panel. On the other hand, the tray door is pushed leftwards because it is in engagement with the pin portion 22a of the link, and although being not shown in FIG. 4, the cams of the tray door are slid on the basis of the cam pins of the front panel, whereby the tray door is lowered to below the tray with the design surface remaining turned upwards to reach a stat near horizontal e, and the tray is slid leftwards on the link and thus completely opened.

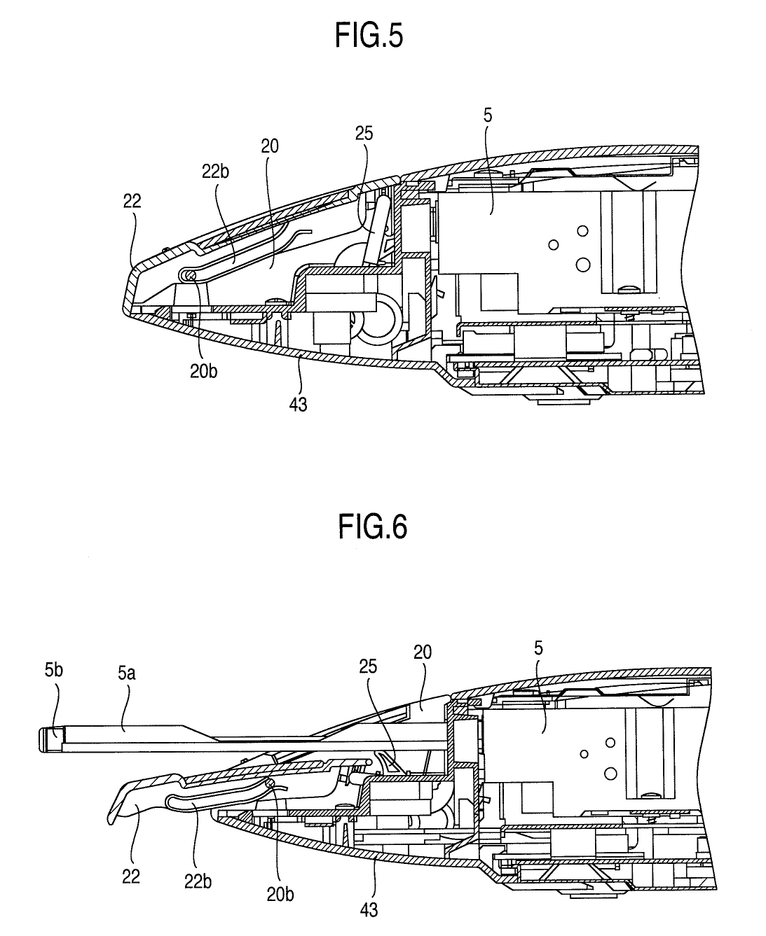

FIG. 5 is a sectional view of the front portion showing a state of the cams of the tray door when the tray door has been closed. The cams 22a are provided on the left and right sides of the tray door and engaged with the cam pin portions 20b of the front panel 20.

FIG. 6 is a sectional view of the front region showing a state of the cams of the tray door when the tray door has been opened. When the link is rotated by the opening and closing movements of the tray, the tray door performs the movement controlled by the rotating motion of the link and the locus of the cams. In a state in which the tray has been opened, the tray door has been lowered to below the tray with its design surface remaining turned upwards to reach the state near horizontal.

FIG. 8 is a perspective view showing the shape of the entire equipment when the tray door has been opened. The tray door 22 has been lowered to below the tray 5a through the link pushed by the tray 5b to reach the state near horizontal.

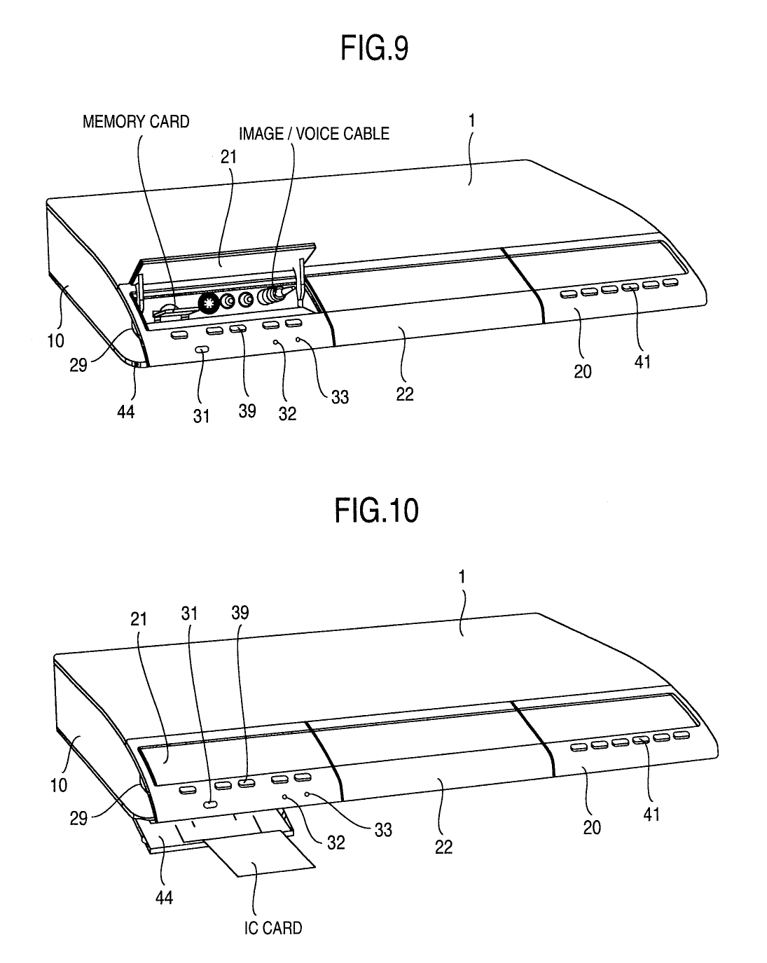

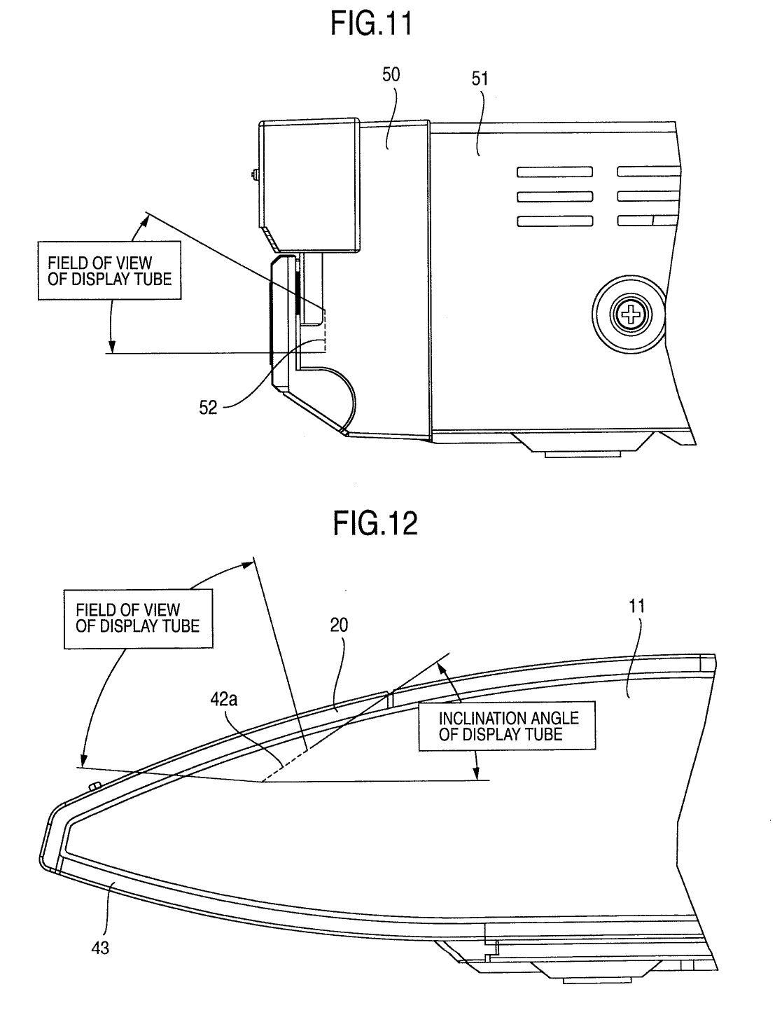

FIG. 9 is a perspective view showing the shape of the entire equipment when a door at a front jack connection portion has been opened. When the locking button 29 is pushed, the jack door 21 biased and pressurized by the leaf spring is opened, thereby making it possible to recognize jacks connecting an image and a voice signal and the memory card slot. A jack memory card is inclined upwards in a range of 10 to 30°, because the jack memory card, if is horizontal, is brought into contact with the front panel located short of it upon connection or insertion thereof.

FIG. 10 is a perspective view showing a shape of the entire equipment when a door at an IC card insertion section has been opened. This embodiment has a digital broadcast receiving function and hence, it is necessary to recognize an IC card. Therefore, a card door 44 is mounted at a left and lower portion of the front panel, and an IC card slot is provided at a location deeper from the card door 44, as well as an IC card 16 is mounted.

FIG. 12 is a side view showing a field of view of a display tube. Reference number 42a designates a viewing position of the display tube showing an operative state of the equipment according to the present invention. In this embodiment, the display tube is inclined at an inclination angle of from 30° to 45° from the horizontal, and a field of view (a field of display view) enabling the recognition of the displaying provided by the display tube is ensured at an angle of 60° or more substantially from the horizontal, leading to an enhancement in visibility of contents displayed when the equipment is placed at a location lower in level.

The electronic equipment according to the present invention is provided with the front panel on the front surface of the equipment, and the link rotatably engaged with the tray door. The tray door is provided with the cams engaged with the cam pins provided on the front panel to control the locus of the movement of the tray door. The link is biased and pressurized by the torsion spring in the rotational direction to push a tray for an optical disc.

Thus, when the user conducts the operation for opening or closing the tray by the remote control or the button on the equipment body in order to eject or retract the optical disc, a control signal indicative of the opening or closing of the tray is transmitted from the system of the equipment to the DVD drive. When the DVD drive receives the control signal indicative of the opening or closing of the tray, the opening or closing of the tray is performed by the power from the motor contained in the DVD drive. When the tray is discharged by the DVD drive, the link is pushed and rotated by the tray, whereby the tray door is slid to below the tray with the design surface thereon left turned upwards in the form of the movement controlled by the rotating motion of the link and the locus of the cams, and in this manner, the tray door is opened. When the tray door is completely opened, the tray is continuously slid on the link in the opening direction. From the foregoing, it is possible to provide an inexpensive and high-quality opening and closing mechanism for the tray door realizing a high-quality design.

It should be further understood by those skilled in the art that although the foregoing description has been made on embodiments of the invention, the invention is not limited thereto and various changes and modifications may be made without departing from the spirit of the invention and the scope of the appended claims.

1. An electronic equipment including a tray capable of being advanced and retreated by a power from a motor, said equipment comprising
a link mounted rotatably relative to the equipment,
a spring for energizing the rotation of said link, and
a tray door mounted on a front surface of the equipment and rotatably engaged with said link, wherein
when said tray is intended to be opened, said tray is advanced, whereby the front end of said tray is put into abutment against said link to rotate the link, causing the tray door rotatably engaged with the link to be opened with the lowering of its deeper portion relative to the equipment by the rotation of the link, and thus, said tray is advanced and opened to lie at the upper portion of the tray door,
when said tray is intended to be closed, said tray is retreated and accommodated into the equipment through a position at an upper portion of said tray door, and
the front end of said tray is disengaged from said link, and said spring biases a portion of said link engaged with said tray to rotate it to a location deeper in the equipment, and the tray door rotatably engaged with said link is lifted to a location deeper in the equipment and thus closed.

2. An electronic equipment according to claim 1, wherein
said tray door is formed so as to position laterally continuous with a front panel forming the front surface of said equipment, and said tray door and said front panel are formed with inclined surfaces with their deeper portions upside and their front portions downside.

3. An electronic equipment according to claim 2, wherein
each of the inclined surfaces of said tray door and said front panel is formed continuously from above to below by a curved surface.

4. An electronic equipment according to claim 2, wherein
said tray door is mounted between the two left and right front panels, and one of said front panels is a front panel mounted at a display portion having an inclination angle, while the other of said front panels is a door at a jack portion having an inclination angle.

5. An electronic equipment including a tray capable of being advanced and retreated by a power from a motor, comprising
a link mounted rotatably relative to the equipment, and
a tray door mounted on a front surface of the equipment and rotatably engaged with said link, wherein
when said tray is intended to be opened, said tray is advanced, whereby said tray is advanced, whereby the front end of said tray is put into abutment against said link to rotate the link, causing the tray door rotatably engaged with the link to be opened with the lowering of its deeper portion relative to the equipment by the rotation of the link, and thus, said tray is advanced and opened to lie at the upper portion of the tray door, and
when said tray is intended to be closed, said tray is retreated and accommodated into the equipment through a position at an upper portion of said tray door,
the tray door rotatably engaged with said link is lifted to a location deeper in the equipment and thus closed.

6. An electronic equipment according to claim 5, wherein
when said tray door has been closed, the deeper end of said tray door relative to the equipment, which is an upper end, is formed to lead to a front end of a top cover of said equipment.

7. An electronic equipment including a tray capable of being advanced and retreated by a power from a motor, said equipment comprising
a front panel having an inclination on an upper surface, to that its front end is vertically tapered, a link rotatably engaged with said front panel, a spring for pressurizing the link in a rotational direction, and a tray door having a hinge portion rotatably engaged with said link, and cams slidably engaged with cam pins provided on said front panel, wherein
the rotation of said link causes said tray door to be lowered to below said tray with its upper surface left turned upwards in the form of the movement controlled by the rotation of said link and the locus of said cams, and in this manner, said tray door is opened.

8. An electronic equipment according to claim 3, wherein
said link is pushed and rotated by said tray advanced by the power from said motor, and said tray door is lowered to below said tray with its upper surface left turned upwards in the form of the movement controlled by the rotation of said link and the locus of said cams, and in this manner, said tray door is opened.
